(19) United States
(12) Patent Application Publication
(10) Pub. No.: US 2012/0133435 A1
(43) Pub. Date: May 31, 2012

(54) Amplification Circuit, Electronic Device, Amplification Method

(76) Inventor: Takeshi Kumagaya, Hachioji-shi (JP)

(21) Appl. No.: 13/233,885

(22) Filed: Sep. 15, 2011

(30) Foreign Application Priority Data
Nov. 30, 2010 (JP) 2010-267832

(51) Int. Cl. H03F 1/00

(52) U.S. Cl. 330/207 R

(57) ABSTRACT

In one embodiment, there is provided an amplification circuit. The amplification circuit includes: a plurality of amplifiers configured to amplify an input signal and output the amplified signal; a control circuit configured to control a current supplied to each of the plurality of amplifiers; and a switching circuit configured to switch the amplified signal output from the plurality of amplifiers in response to current control performed by the control circuit.

### CROSS-REFERENCE TO RELATED APPLICATION

This application claims priority from Japanese Patent Application No. 2010-267832, filed on Nov. 30, 2010, the entire contents of which are hereby incorporated by reference.

### BACKGROUND OF THE INVENTION

1. Field

Embodiments described herein relate to an amplification circuit, an electronic device, and an amplification method.

2. Description of the Related Art

An electronic device capable of wireless communication with another device can receive a signal wirelessly transmitted by the other device. The electronic device amplifies an operation signal on receipt from the other device, using an amplification circuit.

### BRIEF DESCRIPTION OF THE DRAWINGS

A general architecture that implements the various features of the invention will now be described with reference to the drawings. The drawings and the associated descriptions are provided to illustrate embodiments of the invention and not to limit the scope of the invention:

FIG. 1 is a block diagram for explaining a configuration of a common analog/digital tuner related to an exemplary embodiment;

FIG. 2 is a functional block configuration diagram of an RF receiving circuit illustrating an exemplary embodiment;

FIG. 3 is a diagram of switching flow in a low noise amplifier illustrating control of a control circuit in the exemplary embodiment;

FIGS. 4A and 4B are diagrams for explaining an IIC interface according to the exemplary embodiment;

FIG. 5 is a block diagram for explaining another configuration of a common analog/digital tuner; and

FIG. 6 is a block diagram illustrating an example of internal configurations of a DTV and a remote controller in an exemplary embodiment.

### DETAILED DESCRIPTION

According to exemplary embodiments of the present invention, there is provided an amplification circuit. The amplification circuit includes: a plurality of amplifiers configured to amplify an input signal and output the amplified signal; a control circuit configured to control a current supplied to each of the plurality of amplifiers; and a switching circuit configured to switch the amplified signal output from the plurality of amplifiers in response to current control performed by the control circuit.

Explanation follows regarding an exemplary embodiment.

### First Exemplary Embodiment

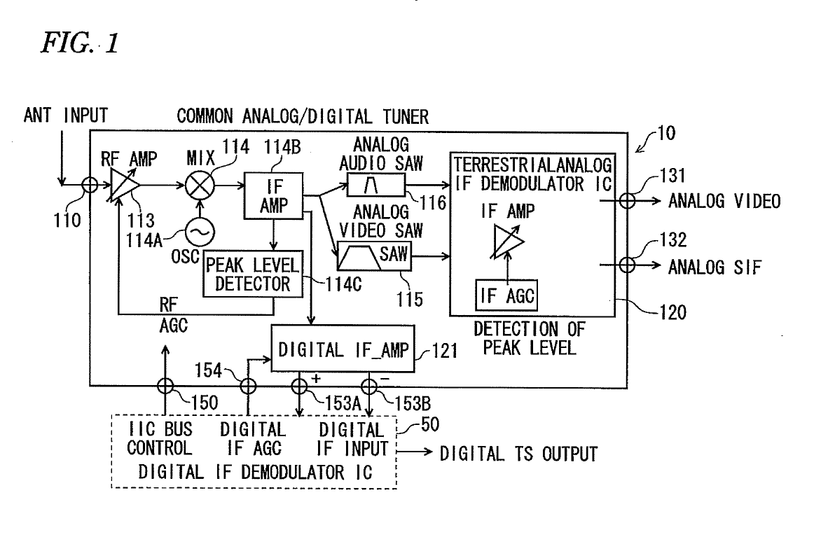

A first exemplary embodiment will be explained, with references to FIGS. 1 through 4. FIG. 1 is a diagram illustrating a configuration of a common analog/digital tuner related to the first exemplary embodiment. First an explanation will be given regarding the configuration.
In FIG. 1, a common analog/digital tuner 10 is used in combination with a terrestrial digital Intermediate Frequency (IF) demodulator IC 50.
The common analog/digital tuner 10 is a module electromagnetically shielded by covering with metal shielding to prevent interference from the terrestrial digital Intermediate Frequency (IF) demodulator IC 50 or another noise emitting source.

The common analog/digital tuner 10 is configured including: a terrestrial broadcast antenna input terminal 110; a variable gain RF_AMP 113; a mixer 114; an oscillator (OSC) 114A; an IF_AMP 114B; a level detector 114C; an analog broadcast picture Intermediate Frequency (IF) filter 115; an analog broadcast audio IF filter 116; a digital broadcast IF_AMP 121; a terrestrial analog IF demodulator IC 120; an analog video signal output terminal 131; and a Sound Intermediate Frequency (SIF) signal output terminal 132.

An IIC bus control terminal 150 is for reception of control through an IIC (I²C, Inter IC) bus from the terrestrial digital IF demodulator IC 50, or from a not illustrated microcomputer connected to the terrestrial digital IF demodulator IC 50. The control function of the microcomputer may be performed by a terrestrial digital IF demodulator IC.

The RF_AMP 113 is controlled by an RF_AGC control signal, and the RF_AMP 113 amplifies the RF signal input from the terrestrial broadcast antenna input terminal 110 and outputs the signal to the mixer 114.

The RF_AMP 113 is a variable gain amplifier. Configuration may be made with provision at the previous stage to the RF_AMP 113 of a fixed gain RF_AMP and an antenna for attenuating the output of the RF_AMP.

The mixer 114 mixes the RF signal from the RF_AMP 113 with the oscillation signal from the OSC 114A and extracts the Intermediate Frequency (IF) components from the mixed signal.

The OSC 114A is a local oscillation circuit with oscillation frequency controlled by a microcomputer, described later, and generates a local oscillation frequency required for viewing the program of the viewer selected station. Portions other than the RF_AMP in the above front end section are often integrated together as a front end IC.

Surface Acoustic Waver (SAW) filters are employed as the analog broadcast picture IF filter 115 and the analog broadcast audio IF filter 116.

The circuit of FIG. 1 is typical to a circuit employed in a television or PC, and configuration elements also have a lot in common to a terminal connected to a wireless LAN. For example, wireless LAN wireless fidelity (Wi-Fi) is a standard for interconnection between wireless devices using an IEEE 802.11 series standard (IEEE 802.11a/IEEE 802.11b) and is employed in VoIP installed mobile phones.

Voice over Internet Protocol (VoIP) is technology for real-time transmission of voice over an Internet Protocol (IP) network by compression with various encoding protocols and packetization.

Among dedicated VoIP devices there are those that use a Session Initiation Protocol (SIP), H.323, IPv4, or IPv6 as a communication protocol. A Wi-Fi phone terminal is a mobile phone capable of direct connection to a wireless LAN.

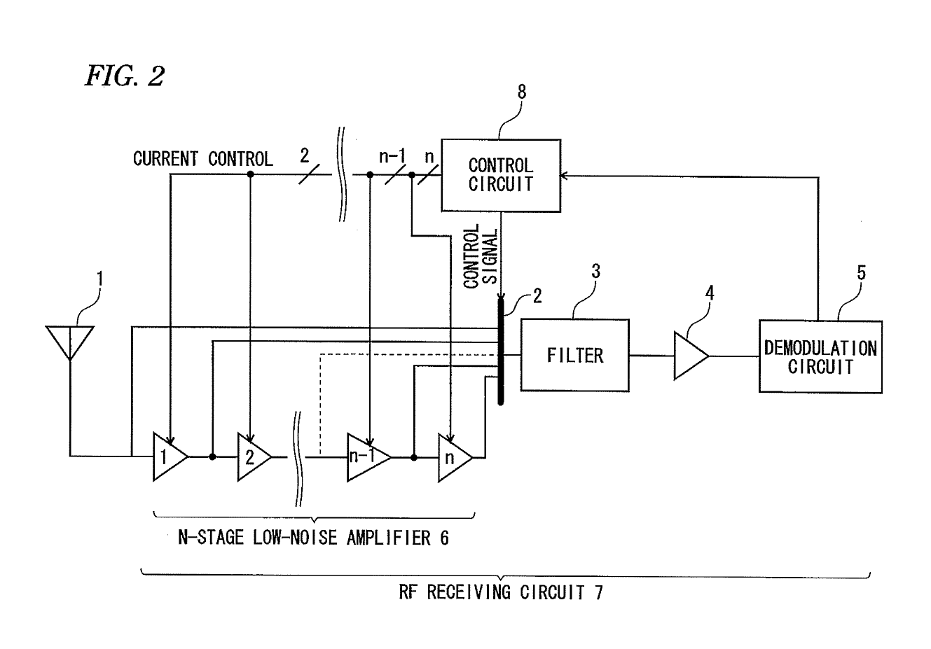

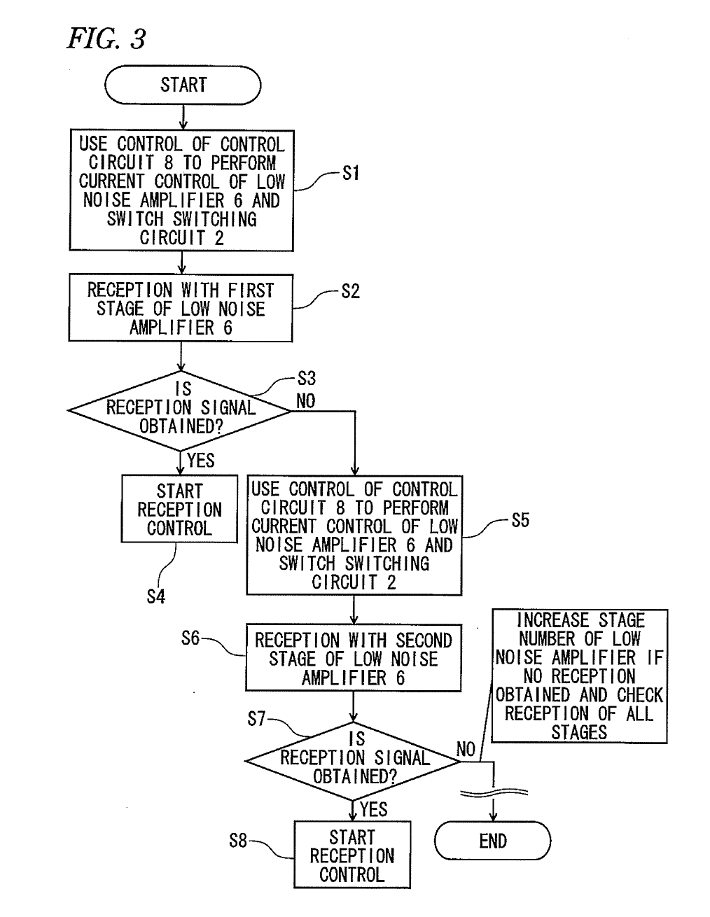

FIG. 2 is a functional block diagram illustration of the first exemplary embodiment, and FIG. 3 illustrates a flow of low noise amplifier switching.

FIG. 2 illustrates an example of a RF receiving circuit 7 connected, for example, to an antenna 1 of a wireless LAN. The RF receiving circuit 7 is configured including a switching circuit 2, a filter 3, a high gain amplifier 4, a demodulation circuit 5, an n-stage low noise amplifier 6 and a control circuit 8 (wherein the “n” in n-stage is an integer, and while n may take the value 1, in the present exemplary embodiment n≧2).

The switching circuit 2 is configured by an analog switch, for example. The control signal from the control circuit 8 may be a binary digital signal, and this digital signal may be passed through a converter and converted into analog levels as required.

Configuration may be provided at a following stage to the switching circuit 2 with a variable gain RF_AMP, and with an antenna to attenuate output before or after the RF_AMP. Configuration may be made such that the output of the variable gain RF_AMP is feedback by detecting the peak level of the Intermediate Frequency (IF) component, or from the demodulation circuit as in a second exemplary embodiment, described later.

A filter 3 includes, for example, a rectifying circuit and BPF. A high gain amplifier 4 is employed for amplifying intermediate frequencies. A demodulation circuit 5 includes a tuner, for example, and demodulates a channel selected by the tuner.

The n-stage low noise amplifier 6 is supplied with power from a not illustrated power source, and power consumption is controlled by current control by the control circuit 8, described later. The control circuit 8 may output the current itself, or output binary voltages for switching, and these binary voltages may be passed through a converter for conversion into current output as required. Configuration may also be made such that in order to determine demodulation in for example, a 2.4 GHz band signal from the demodulation circuit 5, the control circuit 8 is equipped with a comparator in a signal input section, such that demodulation is determined using the output from this comparator.

An example of operation of the RF receiving circuit 7 is given below. As shown in the flow diagram of FIG. 3, when reception of a high-frequency signal from the antenna 1 starts, the control circuit 8 performs current control on the n-stage low noise amplifier 6, and only supplies current to the first stage of the low noise amplifier. The control circuit 8 then controls the switching circuit 2 and selects the output of the first stage low noise amplifier from the n-stage low noise amplifier 6 (step S1, S2). The data output by the switching circuit 2 is input to the control circuit 8 through the filter 3, the high gain amplifier 4, and the demodulation circuit 5. When the control circuit 8 cannot detect a reception signal for, say, 1 second (step S3: No), the control circuit 8 then performs current control of the n-stage low noise amplifier 6 so as to supply current to the second stage. The control circuit 8 then controls the switching circuit 2 and selects the output of the second stage low noise amplifier (steps S5, S6). The data output by the switching circuit 2 is input to the control circuit 8 through the filter 3, the high gain amplifier 4, and the demodulation circuit 5. When the control circuit 8 cannot detect a reception signal (step S7: No), the control circuit 8 then supplies current also to the third stage low noise amplifier (n≧3).

Reception control is started when determination at step S3 is Yes (step S4). This control is, for example, continued until reception is lost, or a user changes channel or switches OFF power to the device. Similar processing to that of the reception control of step S3 is also performed when determination is Yes at step S7.

A reduction in power consumption can be achieved by performing such control such that the current is supplied sequentially from the first stage, in comparison to when current is continuously supplied to all of the low noise amplifiers. Configuration may be made such that reception control is not performed and a message informing that reception control has not been performed is output to a user when current has been supplied up to the n^{th} stage and there is still no reception.

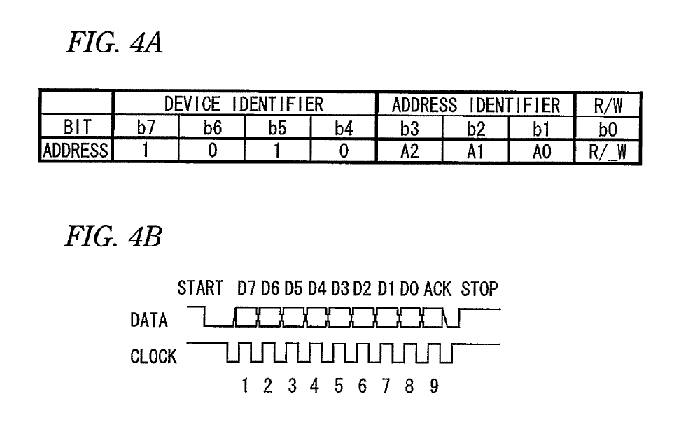

FIGS. 4A and 4B are diagrams for explaining the above IIC interface. The IIC interface bus (IIC-BUS) is realized by two communication lines, one for a clock pulled up from a clock output from a master device, and one for two-way communication of data to-and-fro between master device and slave device.

FIG. 4A illustrates an example of a configuration of a slave address. The slave address is 8-bits long, with the highest value 4 bits fixed according to the type of the device. The lowest value bit means write when it is 0, and read when it is 1.

In practice there are hence only between 1 and 3 bits that can be actually used for the slave address.

FIG. 4B is a schematic diagram of timing in the two lines, with Start being when the level value of the upper data line signal becomes LOW. Data is sent from the highest value bit downwards, and a Stop state adopted when the level value of the signal of the data line becomes HIGH. The corresponding timings of the clock lines are as shown below. FIG. 4B is an example of a single byte transmission, however, this can be repeated plural times up until the data line and ACK are in a stop state, with the initial byte including the slave address, and the remaining bytes allocated to communication contents.

### Second Exemplary Embodiment

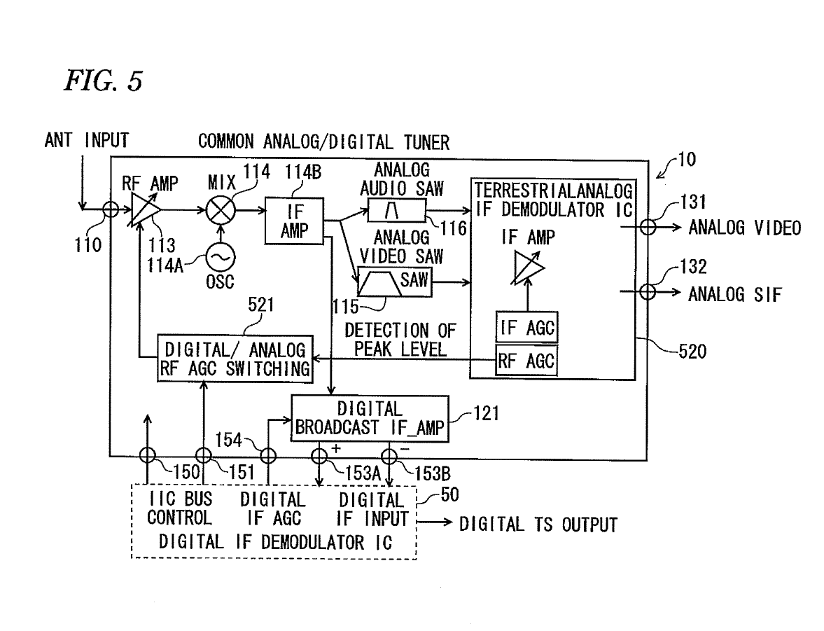

Explanation now follows of a second exemplary embodiment, with reference to FIG. 2 to FIG. 5. Further explanation of portions common to the first exemplary embodiment is omitted. FIG. 5 is a diagram showing a configuration of another common analog/digital tuner. During analog reception with the common analog/digital tuner, an ANT input signal is fed through an RF AMP to a mixer (MIX) where it is mixed with a local oscillator circuit (OSC) frequency to give a 58.75 MHz IF signal which is input to an IF AMP. Signals from the IF AMP are then passed through SAW filters, which ensure that only the band of the desired channel pass through and substantially attenuate adjacent channels, into a terrestrial analog IF demodulation IC. The terrestrial analog IF demodulator IC includes a variable gain internal IF AMP and an IF AGC/RFAGC output/demodulator for performing gain control on the IF AMP.

The AGC system detects an IF AGC/RFAGC control voltage with the terrestrial analog IF demodulator IC after passing through the SAW filters. The IF AMP input after passing through the SAW filters is a lower level compared to FIG. 1, and though this gives less interference at the IF stage, distortion interference more readily occurs at the RF stage due to the adjacent channel level, or digital/analog RF AGC switching is required since the RF AGC loops are different during digital reception as compared to during analog reception. Provision of the level detector 114C, however, becomes unnecessary.

### Third Exemplary Embodiment

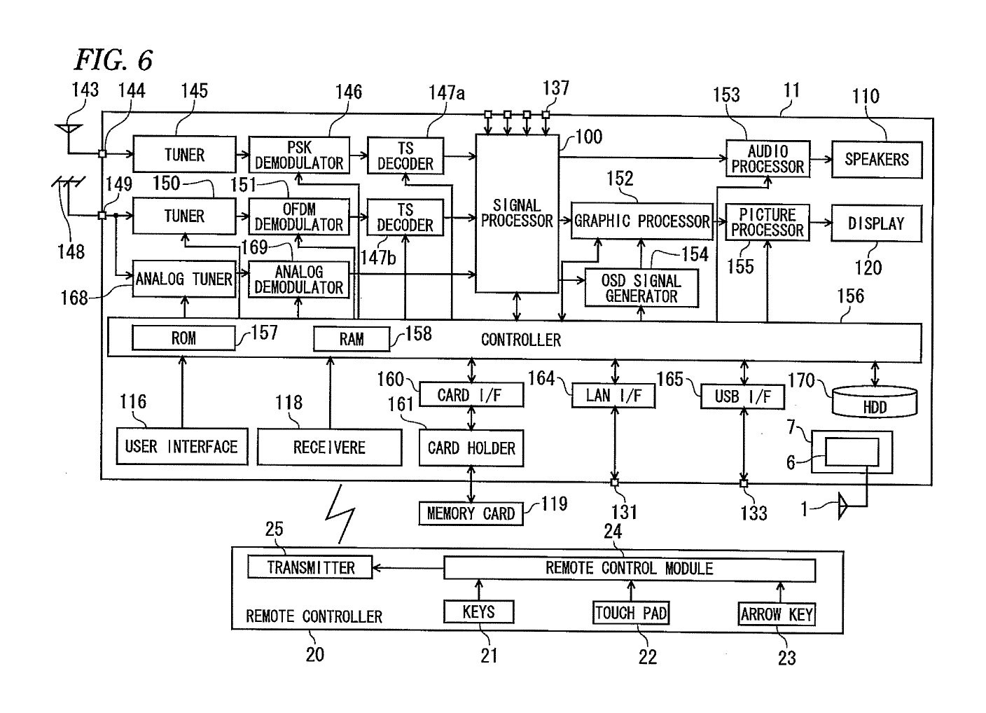

Explanation now follows regarding a third exemplary embodiment with reference to FIG. 6. Further explanation of portions common to the first and second exemplary embodiments is omitted. FIG. 6 is a block diagram showing an example of an internal configuration of a DTV 11 and remote controller 20 in the third exemplary embodiment. An explanation of the DTV 11 follows first. The DTV 11 is provided with a controller 156 for controlling operation of each section of the apparatus. The controller 156 includes, for example, an internal Central Processing Unit (CPU). The controller 156 executes a system control program and various processing programs pre-stored on Read Only Memory (ROM) 157 according to an operation signal input from an user interface 116 and an operation signal received from the remote controller 20 via a receiver 118. The controller 156 controls the operation of each module of the apparatus according to the executed program using Random Access Memory (RAM) 158 as working memory.

An input terminal 144 feeds a satellite digital television broadcast signal received by a BS/CS digital broadcast reception antenna 143 to a tuner 145. The tuner 145 performs tuning on the received digital broadcast signal, and transmits the tuned digital broadcast signal to a Phase Shift Keying (PSK) demodulator 146. The PSK demodulator 146 performs demodulation of the Transport Stream (TS) and supplies the demodulated TS to a TS decoder 147a. After decoding the TS into digital signal including a digital picture signal, a digital audio signal, and a data signal, the TS decoder 147a then outputs the digital signals to a signal processor 100. The digital picture signal here is a digital signal related to a picture capable of being output by the DTV 11, and the audio signal is a digital signal related to sound capable of being output by the DTV 11. The data signal is, for example, a digital signal related to data used when the DTV 11 generates an Electronic Program Guide (EPG), and is data regarding programs to be broadcast, including program related information.

An input terminal 149 feeds a terrestrial digital television broadcast signal received by a terrestrial digital broadcast signal antenna 148 to a terrestrial digital broadcast tuner 150. The terrestrial digital broadcast tuner 150 tunes the received digital broadcast signals and transmits each of the tuned digital broadcast signals to an Orthogonal Frequency Division Multiplexing (OFDM) demodulator 151.

The OFDM demodulator 151 performs TS demodulation and supplies the demodulated TS to respective TS decoders 147b, and the TS decoders 147b output the TS to the signal processor 100 as digital picture signals and audio signals after decoding. Alternatively configuration may be made such that signals are output to the signal processor 100 after each of the 11 individual terrestrial digital television broadcasts acquired by the tuner have been simultaneously decoded by plural individual OFDM demodulators 151 and TS decoders 147b into digital signals, including digital picture signals, digital audio signals and data signals.

The terrestrial digital broadcast signal antenna 148 is also capable of receiving a terrestrial analog broadcast signal. The received terrestrial analog broadcast signal is distributed by a splitter, not illustrated, and fed to an analog tuner 168. The analog tuner 168 tunes the received analog broadcast signal, and transmits the tuned analog broadcast signal to an analog demodulator 169. The analog demodulator 169 demodulates the analog broadcast signal and outputs the demodulated analog broadcast signal to the signal processor 100. The DTV 11 can also be employed for viewing CATV by, for example, connecting a Common Antenna Television (CATV) tuner to the input terminal 149 to which the terrestrial digital broadcast signal antenna 148 is connected.

The signal processor 100 performs appropriate signal processing on the digital signal output from the TS decoder 147a, 147b or from the controller 156. More specifically, the signal processor 100 separates the digital signal into a picture signal, a digital audio signal, and a data signal. The separated picture signal is output to a graphic processor 152 and the separated audio signal is output to an audio processor 153. The signal processor 100 converts the broadcast signal output from the analog demodulator 169 into a picture signal and audio signal of a specific format. The digitally converted picture signal and audio signal are output to the graphic processor 152 and the audio processor 153, respectively. The signal processor 100 performs specific digital signal processing on the input signal from a line input terminal 137.

An On Screen Display (OSD) signal generator 154 generates an OSD signal under control from the controller 156, for display on a User Interface (UI) screen. In the signal processor 100, the data signal separated from the digital signal is converted into an OSD signal of an appropriate format by the OSD signal generator 154, and output to the graphic processor 152.

The graphic processor 152 performs decoding processing on the digital picture signal output from the signal processor 100. The decoded picture signal is superimposed and combined with the OSD signal output from the OSD signal generator 154 and output to a picture processor 155. The graphic processor 152 is capable of selectively outputting either the decoded picture signal and/or the OSD signal to the picture processor 155.

The picture processor 155 converts the signal output from the graphic processor 152 into an analog video signal of a format displayable on a display 120. The analog converted picture signal is displayed on the display 120.

The audio processor 153 converts the input audio signal into an analog audio signal reproducible on speakers 110.

A card holder 161 is connected to a controller 156 through a card interface (I/F) 160. A memory card 119 is installable in this card I/F 160. The memory card 119 is a storage medium, such as a Secure Digital (SD) memory card, a Multimedia Card (MMC) or a COMPACTFLASH (registered trademark) card.

The controller 156 can write and read data from the memory card 119 installed in the card holder 161 via the card I/F 160.

A LAN terminal 131 is connected to the controller 156 through a LAN I/F 164. The LAN terminal 131 is employed as a general LAN compatible port employing ETHERNET (registered trademark). In the third exemplary embodiment a LAN cable (not shown in the drawings) is connected to the LAN terminal 131, enabling communication with the Internet.

A Universal Serial Bus (USB) terminal 133 is connected to the controller 156 via a USB I/F 166. The USB terminal 133 is employed as a general USB compatible port. A mobile phone, digital camera, card reader/writer for various memory cards, HDD and/or keyboard may, for example, be connected to the USB terminal 133 through a bus.

The controller 156 can communicate (transmit and receive) data to-and-from devices connected through the USB terminal 133.

The HDD 170 is an internal magnetic storage medium (Hard Disk Drive) of the DTV 11 with functionality for storing various data for the DTV 11. The signal demodulated by the RF receiving circuit 7 is led to and used as the signal for the TS decoder 147a or other similar not illustrated decoder. Configuration may be made such that an IIC interface is employed for intercommunication between the RF receiving circuit and other blocks within the DTV 11, or using other means.

Explanation now follows regarding the remote controller 20. Detected signals output by keys 21, a touch pad 22, or a arrow key 23 are input to a remote control module 24. Based on the signal input, the remote control module 24 generates an operation signal for operating the DTV 11, and externally transmits the signal with a transmitter 25. When the transmitted operation signal is received by the receiver 118 the DTV 11 then executes a specific processing according to the operation signal.

In the third exemplary embodiment the signal transmitted from the remote controller 20 when the keys 21 are pressed is referred to as the key operation signal, the signal transmitted by a trace on the touch pad 22 is referred to as the touch panel operation signal, and the signal transmitted by depressing the arrow key 23 as the arrow key operation signal.

According to the exemplary embodiment as described above, by provision of the control circuit and switching circuit, the number of stages of a low noise amplifier can be adjusted according to the distance to a transmitter (for example an access point of a Wi-Fi wireless LAN), thereby enabling a reduction in power consumption to be achieved.

A reduction in power consumption effect is hence achieved in an RF receiving circuit connected to a multi-stage amplifier by switching the amplifier stage number during reception signal searching.

Note that there is no limitation to the exemplary embodiments described above, and various modifications may be implemented within a scope not departing from the spirit. For example, configuration may be made such that the characteristics such as the amplification ratio of each of the stages of the n-stage low noise amplifier 6 are different from each other. It is also not essential to check reception from the first stage. When living or staying in an area with weak signals, such as a mountainous area, configuration can be made such that reception confirmation starts at the second stage or higher, for example either by dialogue user setting using the remote controller 20 or by self-training of the apparatus itself.

While certain embodiments have been described, these embodiments have been presented by way of example only, and are not intended to limit the scope of the invention. Indeed, the novel methods and systems described herein may be embodied in a variety of other forms. Furthermore, various omissions, substitutions and changes in the form of the methods and systems described herein may be made without departing from the sprit of the invention. The accompanying claims and their equivalents are intended to cover such forms or modifications as would fall within the scope and sprit of the invention.

What is claimed is:

1. An amplification circuit comprising:
a plurality of amplifiers configured to amplify an input signal and output the amplified signal;
a control circuit configured to control a current supplied to each of the plurality of amplifiers; and
a switching circuit configured to switch the amplified signal output from the plurality of amplifiers in response to current control performed by the control circuit.

2. The amplification circuit of claim 1, wherein the plurality of amplifiers are low noise amplifiers.

3. An electronic circuit comprising:
an amplification circuit that comprises (i) a plurality of amplifiers configured to amplify an input signal and output the amplified signal, (ii) a control circuit configured to control a current supplied to each of the plurality of amplifiers, and (iii) a switching circuit configured to switch the amplified signal output from the plurality of amplifiers in response to current control performed by the control circuit; and
a filter configured to filter a signal output from the switching circuit.

4. The electronic circuit of claim 3 further comprising a demodulation circuit configured to demodulate a signal output from the filter.

5. The electronic circuit of claim 3 further comprising an antenna coupled to the amplification circuit, the antenna being configured to receive a signal and provide an output signal from the antenna, wherein the output signal from the antenna is the input signal amplified by the amplification circuit.

6. The electronic circuit of claim 3, wherein the plurality of amplifiers of the amplification circuit are low noise amplifiers.

7. An electronic device comprising:
an antenna configured to receive a signal;
an amplification circuit comprising:
a plurality of amplifiers configured to amplify a signal output from the antenna and output the amplified signal;
a control circuit configured to control a current supplied to each of the plurality of amplifiers; and
a switching circuit configured to switch the amplified signal output from the plurality of amplifiers in response to current control performed by the control circuit; and
a demodulation circuit configured to demodulate a signal output from the amplification circuit.

8. An amplification method comprising:
(a) controlling a current supplied to each of a plurality of amplifiers, wherein the plurality of amplifiers are configured to amplify an input signal and output an amplified signal; and
(b) switching the amplified signal output from the plurality of amplifiers in response to the controlling of the current.
